(19) United States
(12) Patent Application Publication
(10) Pub. No.: US 2026/0239718 A1
(43) Pub. Date: Aug. 13, 2026

(54) METHOD FOR FORMING A SHARED CONTACT HOLE AND A SEMICONDUCTOR STRUCTURE

(71) Applicant: Shanghai Huali Integrated Circuit Corporation, Shanghai (CN)

(72) Inventors: Yu XIA, Shanghai (CN); Jionghan YE, Shanghai (CN)

(73) Assignee: Shanghai Huali Integrated Circuit Corporation, Shanghai (CN)

(21) Appl. No.: 19/091,866

(22) Filed: Mar. 27, 2025

(30) Foreign Application Priority Data
Feb. 11, 2025 (CN) 2025101528889

(51) Int. Cl. H10D 84/01; H10D 84/83

(52) U.S. Cl. CPC H10D 84/0149; H10D 84/83

(57) ABSTRACT

A method for forming a shared contact hole and a semiconductor structure is provided. First, the first hard mask layer is formed on the region where the shared contact hole needs to be formed on the gate structures. Then, the step-by-step etching process ensures that the etching endpoint stops on the first hard mask layer and the second hard mask layer during the etching of the first interlayer dielectric layer, thereby preventing over-etching of the metal gate and the generation of by-products. Subsequently, the first hard mask layer and the second hard mask layer are completely etched to expose portions of the active regions and the metal gate to finally form a shared contact hole. The conductive layer formed in the shared contact hole ensures sufficient contact between the active regions and the metal gate, ultimately improving the yield and reliability of the semiconductor device.

### FIELD OF TECHNOLOGY

The present disclosure relates to the technical field of semiconductor integrated circuit manufacturing, and particularly to a method for forming a shared contact hole in a semiconductor structure.

### BACKGROUND

With the rapid development of integrated circuit technology, the size of transistors continues to reduce to achieve higher integration level and more powerful functions. However, the continuous shrinking size of transistors also brings great challenges to process development. In the preparation process of semiconductor devices, contact holes (CT) usually play a vital role. They are responsible for connecting the source, drain, and gate of transistors with interconnecting metal layers first before linking the semiconductor devices to external circuits where the function of the device is brought into play.

The conventional contact hole (ordinary CT for short) is designed as a square on the mask and exhibits a columnar structure after preparation. However, with the continuous change of process requirements, some semiconductor manufacturing processes require the simultaneous connection of multiple metal gates, source, and drain regions, but the traditional contact holes cannot support such semiconductors, thus deriving a need for shared contact holes (Share CT).

Although a shared contact hole can connect the metal gate, source, and drain regions at the same time, there are significant differences in the morphology between the shared contact hole and ordinary CT, this difference also brings challenges to the process window of the contact manufacturing process. On the one hand, the thin film composition of the shared contact hole is different from that of the ordinary CT, so the shared contact hole cannot be connected normally to the metal gate or source and drain regions in the etching process, as the ordinary CT would be. but. In addition, it is easier for the shared contact hole to get close to the metal gate during the etching process, thus to pick up etch by-products produced by the metal gate produces. These by-products may fall on the active regions and block etching, resulting in poor contact between the conductive layer formed in the shared contact hole and the metal gate or the active region. This has been observed in the device region of NMOS.

At present, there has been no effective method to improve the by-product etch-blocking problem in shared contact holes. Therefore, there is an urgent need to solve the problems, so as to ensure that the conductive layer formed in the shared contact hole forms good contact with the active region and the metal gate.

It should be noted that the above introduction to the technical background is only for providing a clear and complete explanation of the technical solution and facilitating understanding by technical personnel in this field. The above technical solutions should not be considered as known to technical personnel in this field simply because they are described in this application's background section. The existence of this problem affects the manufacturing yield of shared contact, in turn affects the performance and reliability of integrated circuits.

### SUMMARY

The present disclosure provides a method for forming a shared contact hole in a semiconductor structure, thus solving the problem of shared contact hole's poor connection to metal gate and/or source and drain regions due to the by-product generated during over-etching the metal gate.

The method includes:
providing a semiconductor substrate, forming two or more active regions and a shallow trench isolation located between the two or more active regions on the semiconductor substrate, forming a plurality of gate structures on the two or more active regions, forming a second hard mask layer on top surfaces and side walls of the plurality of gate structures, and performing a planarization process on the plurality of gate structures to remove the second hard mask layer from the top surfaces of the plurality of gate structures;
forming a first hard mask layer on the gate structures, etching the first hard mask layer to remove a portion of the first hard mask layer, wherein the remaining first hard mask layer covers a region where a shared contact hole needs to be formed;
forming a first interlayer dielectric layer on the gate structures, wherein the first interlayer dielectric layer covers the gate structures and the first hard mask layer;
performing a first etching process on the first interlayer dielectric layer and etching to remove the first interlayer dielectric layer, thereby forming an opening between the adjacent gate structures, wherein the opening exposes the first hard mask layer and a second hard mask layer located in the gate structures;
performing a second etching process on the first hard mask layer and the second hard mask layer based on the opening, and etching to remove the exposed first hard mask layer and the second hard mask layer, thereby forming a shared contact hole.

Optionally, before performing the planarization process, forming a silicide layer located between two adjacent ones of the plurality of gate structures and on the two or more active regions, and forming a second dielectric layer above the silicide layer and between the two adjacent ones of the plurality of gate structures, and wherein the plurality of gate structures each comprises a metal gate.

Optionally, a material of the metal gate includes one or more of aluminum, titanium, tantalum, zirconium, cobalt, nickel, and oxides thereof.

Optionally, a thickness of the first hard mask layer is equal to a thickness of the second hard mask layer.

Optionally, the first etching process selects high selectivity etching of the first interlayer dielectric layer with respect to the first hard mask layer and the second hard mask layer, and the second etching process selects high selectivity etching of the first hard mask layer and the second hard mask layer with respect to the first interlayer dielectric layer.

Optionally, the material of the first hard mask layer includes one or more of silicon oxide, silicon nitride, silicon oxynitride, silicon carbide, silicon carbonitride, boron nitride, tantalum nitride, or titanium nitride, and the material of the second hard mask layer includes one or more of silicon oxide, silicon nitride, silicon oxynitride, silicon carbide, silicon carbonitride, boron nitride, tantalum nitride, or titanium nitride.

Optionally, after forming the shared contact hole, the step further includes depositing a metal in the shared contact hole to form a conductive layer, and the conductive layer is in contact with the silicide layer and the metal gate to form an electrical connection.

Optionally, the semiconductor substrate includes an NMOS device region, and the gate structures are formed on the semiconductor substrate of the NMOS device region.

The present disclosure also provides a semiconductor structure, the semiconductor structure is formed by the above-described method for forming a shared contact hole, wherein the semiconductor structure includes:

A semiconductor substrate, wherein two or more active regions and shallow trench isolation located between the active regions are formed on the semiconductor substrate, and a plurality of gate structures are formed on the active regions;
a first hard mask layer, wherein the first hard mask layer is located on top of the gate and covers a region where a shared contact hole needs to be formed;
a first interlayer dielectric layer, wherein the first interlayer dielectric layer covers the gate structures and the first hard mask layer;
a shared contact hole, wherein the shared contact hole is located on the gate structures and exposes portions of the active region and the gate structures;
a conductive layer, wherein the conductive layer is located at the shared contact hole and in contact with the active region and the gate structures.

Optionally, the metal gate includes one or more of aluminum, titanium, tantalum, zirconium, cobalt, nickel, and oxides thereof.

As described above, the method for forming the shared contact hole and the semiconductor structure of the present disclosure has the following beneficial effects: by forming the first hard mask layer on the region where the shared contact hole needs to be formed on the gate structures, precise protection of the boundary region between the active regions and the metal gate region is achieved, and the issue of potential metal gate damage in traditional etching processes is resolved. In addition, the step-by-step etching process ensures that the etching endpoint stops on the first hard mask layer and the second hard mask layer during the etching of the first interlayer dielectric layer, thereby preventing over-etching of the metal gate and the generation of by-products. Subsequently, the first hard mask layer and the second hard mask layer are completely etched to expose portions of the active regions and the metal gate to finally form a shared contact hole, and the conductive layer formed in the shared contact hole ensures sufficient contact between the active regions and the metal gate, ultimately improving the yield and reliability of the semiconductor device.

### BRIEF DESCRIPTION OF THE DRAWINGS

FIG. 1 is a schematic flow diagram showing a method for forming a shared contact hole according to the present disclosure.

FIG. 2 is a schematic structural diagram of a shared contact hole in a substrate according to the present disclosure.

FIG. 3 is a schematic structural diagram showing a structure after forming a first hard mask layer according to the present disclosure.

FIG. 4 is a schematic structural diagram showing a structure after forming a first interlayer dielectric layer in the present disclosure.

FIG. 5 is a schematic structural diagram showing a structure after performing a first etching process according to the present disclosure.

FIG. 6 is a schematic structural diagram showing a structure after performing a second etching process according to the present disclosure.

FIG. 7 is a schematic structural diagram showing clean shared contact holes according to the present disclosure.

FIG. 8 shows a schematic structural diagram after forming a conductive layer in the clean shared contact holes, and a semiconductor formed by the method according to the present disclosure.

### REFERENCE NUMERALS

10. Substrate; 11. Active Region; 12. Silicide Layer; 13. Second Hard Mask Layer; 14. Second Dielectric Layer; 15. Metal Gate; 16. Shallow Trench Isolation; 17. First Hard Mask Layer; 18. First Interlayer Dielectric Layer; 19. Opening; 20. Shared Contact Hole; 21. Conductive Layer; S1 to S5: Steps.

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

In detailed description of embodiments of the present disclosure, for convenience of illustration, the schematic drawings showing the structure of the apparatus will not be partially enlarged according to the general scale, and the schematic drawings are merely examples, and should not limit the scope of protection of the present disclosure herein. In addition, the actual production should comprise the length, width, and depth of the three-dimensional space dimensions.

For convenience of description, spatially relational words such as “below,” “above,” “above,” etc. may be used herein to describe the relationship of one element or feature to other elements or features illustrated in the drawings. It will be understood that these spatial relationship terms are intended to encompass directions/orientations of the device in use or operation other than those depicted in the drawings.

In the context of this disclosure, the structure described with a first feature “on top” of a second feature may include embodiments where the first and second features are formed in direct contact, or it may include embodiments where additional features are formed between the first and second features such that the first and second features are not in direct contact.

It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

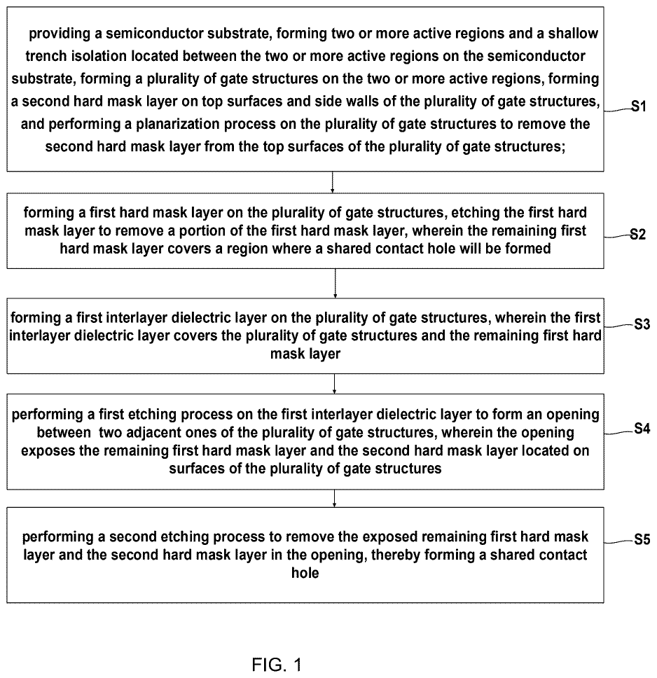

As shown in FIG. 1, the present disclosure provides a method for forming a shared contact hole, the method for forming a shared contact hole includes the following steps:

S1: providing a semiconductor substrate 10, wherein two or more active regions 11 and a shallow trench isolation 16 located between the active regions 11 are formed on the semiconductor substrate 10, and a plurality of gate structures are formed on the active regions 11 and a planarization process is performed on the gate structures;

S2: forming a first hard mask layer 17 on the gate structures, etching the first hard mask layer 17 to remove a portion of the first hard mask layer 17, wherein the remaining first hard mask layer 17 covers a region where the shared contact hole 20 needs to be formed;

S3: forming a first interlayer dielectric layer 18 on the gate structures, wherein the first interlayer dielectric layer 18 covers the gate structures and the first hard mask layer 17;

S4: performing a first etching process on the first interlayer dielectric layer 18 and etching to remove the first interlayer dielectric layer 18, thereby forming an opening 19 between adjacent gate structures. The opening 19 expose the first hard mask layer 17 and the second hard mask layer 13 located in the gate structures;

S5: performing a second etching process on the first hard mask layer 17 and the second hard mask layer 13 based on the opening 19, and etching to remove the exposed first hard mask layer 17 and the second hard mask layer 13, thereby forming a shared contact hole 20.

It should be noted that the above sequence does not strictly represent the sequence of the method for forming the shared contact hole 20 protected by the present disclosure, and those skilled in the art can change it according to the actual preparation steps, and the method for forming the shared contact hole 20 will be further described below with reference to the drawings, as follows:

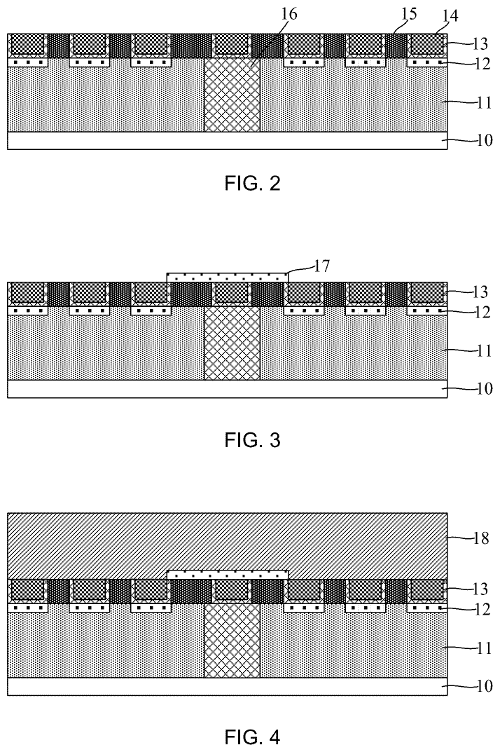

In step S1, referring to FIG. 1 and FIG. 2, a semiconductor substrate 10 is provided, and two or more active regions 11 and a shallow trench isolation 16 located between the active regions 11 are formed on the semiconductor substrate 10, and a plurality of gate structures are formed on the active regions 11 and a planarization process is performed on the gate structures.

As shown in FIG. 2, a semiconductor substrate 10 is provided. The semiconductor substrate 10 may be a silicon substrate 10 with a single-crystal or polycrystalline structure. It may also include one or more of silicon on insulator (SOI), silicon germanium on insulator (SiGeOI), and germanium on insulator (GeOI). Additionally, the semiconductor substrate 10 may include other types, such as compound semiconductors and/or alloy semiconductors, for example, gallium nitride or gallium arsenide. In this embodiment, a common single-crystal silicon substrate 10 is selected as the semiconductor substrate 10, and the semiconductor substrate 10 includes an NMOS device region, and the gate structures are formed on the semiconductor substrate 10 of the NMOS device region.

One or two active regions 11 are formed on the semiconductor substrate 10, with a shallow trench isolation 16 structure formed between the two active regions 11. Exemplarily, a method for forming a shallow trench isolation 16 structure in a semiconductor substrate 10 includes: first forming a patterned hard mask layer on a surface of the semiconductor substrate 10; etching with the patterned hard mask layer as a mask to form a shallow trench; filling the shallow trench, planarizing the filled shallow trench, and removing the hard mask layer to obtain the shallow trench isolation 16 structure. Non-limiting examples of such planarization methods include mechanical planarization methods and chemical mechanical polishing planarization methods. Generally, the chemical mechanical polishing planarization method is preferred. Preferably, the top surface of the shallow trench isolation 16 structure is flush with the surface of the semiconductor substrate 10.

A plurality of gate structures are formed above the active region 11 and the shallow trench isolation 16 structure, wherein each of the gate structures includes a silicide layer 12 located within the active regions 11 and a second dielectric layer 14 located above the silicide layer 12, wherein the second hard mask layer 13 is further formed on a sidewall and a bottom of the second dielectric layer 14, and a metal gate 15 is further formed between the adjacent second hard mask layers 13 located on the sidewalls of the second dielectric layer 14. The material of the metal gate 15 includes one or more of aluminum, titanium, tantalum, zirconium, cobalt, nickel and oxides thereof. The second dielectric layer 14 is located directly above the silicide layer 12, and the width of the second dielectric layer 14 and the second hard mask layer 13 on both sides is equal to the width of the silicide layer 12. The second hard mask layer 13 located at the bottom of the second dielectric layer 14 serves as a contact hole etching stop layer during the etching of contact hole, and the material of the second hard mask layer 13 includes one or more of silicon oxide, silicon nitride, silicon oxynitride, silicon carbide, silicon carbonitride, boron nitride, tantalum nitride, and titanium nitride. For example, the material of the second hard mask layer 13 is silicon nitride. The planarization process is carried out on the top of the gate structures to obtain a flat surface, which is helpful to improve the yield of the formed semiconductor structure. Non-limiting examples of such planarization methods include mechanical planarization methods and chemical mechanical polishing planarization methods. Generally, the chemical mechanical polishing planarization method is preferred. It should be understood that the gate structures in this embodiment are tailored for the metal-gate gate-last process, but the present disclosure is not limited thereto, and other gate structures may also be employed.

In step S2, referring to FIG. 1 and FIG. 3, a first hard mask layer 17 is formed on the gate structures and the first hard mask layer 17 is etched to remove a portion of the first hard mask layer 17, and the remaining first hard mask layer 17 covers a region where the shared contact hole 20 needs to be formed.

In this embodiment, as shown in FIG. 3, a dielectric material is deposited on the gate structures using a chemical vapor deposition process to form the first hard mask layer 17. The material of the first hard mask layer 17 includes any one of silicon oxide, silicon nitride, silicon oxynitride, silicon carbide, silicon carbonitride, boron nitride, tantalum nitride, or titanium nitride. For example, the first hard mask layer may be silicon nitride. Since multiple etching steps are required only for the region where the shared contact hole 20 needs to be formed, it is necessary to first perform preliminary etching on the first hard mask layer 17 to remove a portion of the first hard mask layer 17, leaving only the portion of the first hard mask layer 17 located above the region where the shared contact hole 20 is to be formed. The first hard mask layer 17 serves as a contact hole etching stop layer during the etching of the shared contact hole 20.

As an example, the thickness of the first hard mask layer is equal to the thickness of the second hard mask layer. Specifically, the thickness of the first hard mask layer is set to be equal to the thickness of the second hard mask layer, so that the first hard mask layer 17 and the second hard mask layer 13 can be completely removed at the same time during the second etching, thereby reducing the production cost.

In step S3, referring to FIG. 1 and FIG. 4, a first interlayer dielectric layer 18 is formed on the gate structures, and the first interlayer dielectric layer 18 covers the gate structures and the first hard mask layer 17.

As shown in FIG. 4, a first interlayer dielectric layer 18 is formed on the gate structures, and the material of the first interlayer dielectric layer 18 may be one or more of silicon oxide, silicon nitride, and silicon oxynitride, and the height of the first interlayer dielectric layer 18 is greater than the height of the first hard mask layer. Specifically, in this embodiment, the material of the first interlayer dielectric layer 18 is silicon oxide, which can be formed by an atomic layer deposition method (ALD).

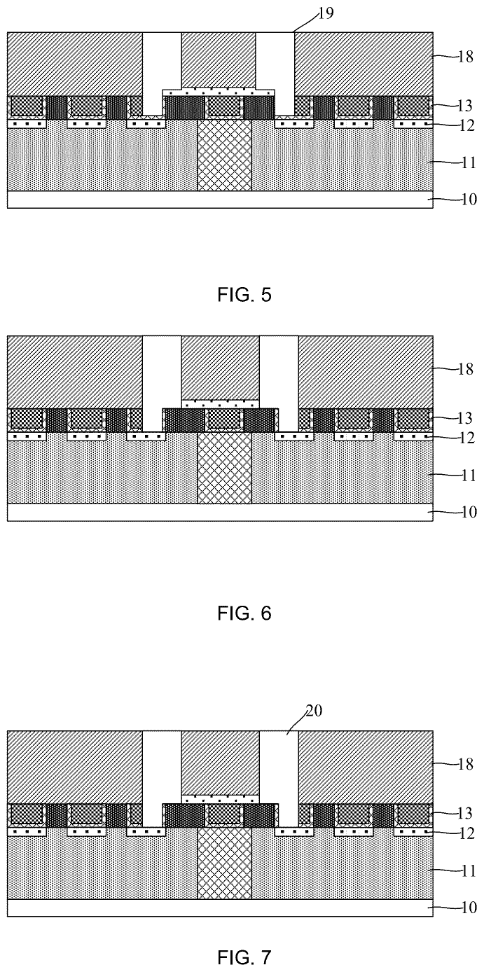

In step S4, referring to FIG. 1 and FIG. 5, a first etching process is performed on the first interlayer dielectric layer 18 to remove the first interlayer dielectric layer 18, thereby forming an opening 19 between adjacent gate structures. The opening 19 exposes the first hard mask layer 17 and the second hard mask layer 13 located in the gate structures.

Referring to FIG. 5, a first etching process is performed, specifically, a photoresist masking layer is formed on the first interlayer dielectric layer 18, and the photoresist masking layer is exposed and developed to form a patterned photoresist masking layer. Based on the patterned photoresist masking layer, the first interlayer dielectric layer 18 is etched back to form an opening 19 in the region where the shared contact hole 20 needs to be formed. The opening 19 spans across the metal gate 15 and the silicide layer 12.

The first etching process is selected to have the high selectivity ratio of the first interlayer dielectric layer 18 to the first hard mask layer 17 and the second hard mask layer 13. As a result, upon completion of the first etching process, the etching endpoint stops on the first hard mask layer 17 and the second hard mask layer 13. Compared to the case where the first hard mask layer 17 is not formed, the first etching process does not etch into the metal gate 15 during the etching process, thereby preventing the generation of etching by-products and ensuring the quality of the formed shared contact hole 20.

In step S5, referring to FIG. 1 and FIG. 6, a second etching process is performed on the first hard mask layer 17 and the second hard mask layer 13 based on the opening 19, thereby removing the exposed portions of the first hard mask layer 17 and the second hard mask layer 13 to form the shared contact hole 20.

Referring to FIG. 6, a second etching process is performed. Specifically, the second etching process is selected to have the high selectivity ratio of the first hard mask layer 17 and the second hard mask layer 13 to the first interlayer dielectric layer 18. As a result, upon completion of the second etching process, the first hard mask layer 17 and the second hard mask layer 13 located within the opening 19 are completely removed, and the formed shared contact hole 20 exposes the silicide layer 12 located in the active regions 11 and the metal gate 15.

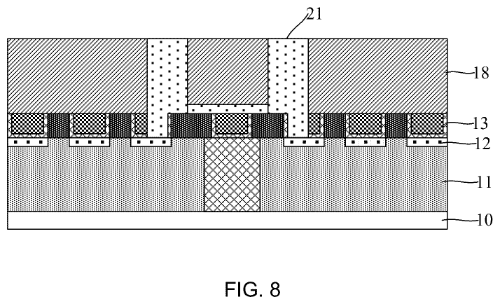

After the step of forming the shared contact hole 20, referring to FIG. 8, depositing a conductive material like a metal in the shared contact hole 20 to form a conductive layer 21, which can be formed by a physical vapor deposition process. The conductive layer 21 is made of materials such as tungsten and is planarized by a chemical mechanical polishing process to ensure the top of the conductive layer 21 has a flat surface. The conductive layer 21 forms a good contact with the silicide layer 12 and the metal gate 15 in the active regions 11 to achieve a better electrical connection.

In another embodiment of the present disclosure, a semiconductor structure is also proposed, and the semiconductor structure is formed by the above-described method for forming the shared contact hole 20. As shown in FIG. 8, the semiconductor structure includes a semiconductor substrate 10 on which two or more active regions 11 are formed, a shallow trench isolation 16 located between the active regions 11, and a plurality of gate structures are formed on the active regions 11. a first hard mask layer 17, wherein the first hard mask layer 17 is located on top of the gate and covers a region where a shared contact hole 20 needs to be formed; a first interlayer dielectric layer 18, wherein the first interlayer dielectric layer 18 covers the gate structures and the first hard mask layer 17; a shared contact hole 20, wherein the shared contact hole 20 is located on the gate structures and exposes portions of the active regions 11 and the gate structures; a conductive layer 21, wherein the conductive layer 21 is located on the shared contact hole 20 and connected to the active regions 11 and the gate structures.

As an example, the metal gate 15 includes one or more of aluminum, titanium, tantalum, zirconium, cobalt, nickel, and oxides thereof.

In summary, the method for forming the shared contact hole and the semiconductor structure of the present disclosure realizes precise protection of the boundary region between the active regions and the metal gate region by first forming the first hard mask layer on the region where the shared contact hole needs to be formed on the gate structures, and solves the problem of metal gate damage that may be caused in the traditional etching process. In addition, the step-by-step etching process ensures that the etching endpoint stops on the first hard mask layer and the second hard mask layer during the etching of the first interlayer dielectric layer, thereby preventing over-etching of the metal gate and the generation of by-products. Subsequently, the first hard mask layer and the second hard mask layer are completely etched to expose portions of the active regions and the metal gate to finally form a shared contact hole, and the conductive layer formed in the shared contact hole ensures sufficient contact between the active regions and the metal gate, ultimately improving the yield and reliability of the semiconductor device. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge of the art without departing from the spirit and technical concept disclosed by the present disclosure shall be still covered by the claims of the present disclosure.

What is claimed is:

1. A method for forming a shared contact hole in a semiconductor device, comprising:
providing a semiconductor substrate, forming two or more active regions and a shallow trench isolation located between the two or more active regions on the semiconductor substrate, forming a plurality of gate structures on the two or more active regions, forming a second hard mask layer on top surfaces and side walls of the plurality of gate structures, and performing a planarization process on the plurality of gate structures to remove the second hard mask layer from the top surfaces of the plurality of gate structures;
forming a first hard mask layer on the plurality of gate structures, etching the first hard mask layer to remove a portion of the first hard mask layer, wherein the remaining first hard mask layer covers a region where a shared contact hole will be formed;
forming a first interlayer dielectric layer on the plurality of gate structures, wherein the first interlayer dielectric layer covers the plurality of gate structures and the remaining first hard mask layer;
performing a first etching process on the first interlayer dielectric layer to form an opening between two adjacent ones of the plurality of gate structures, wherein the opening exposes the remaining first hard mask layer and the second hard mask layer located on surfaces of the plurality of gate structures; and
performing a second etching process to remove the exposed remaining first hard mask layer and the second hard mask layer in the opening, thereby forming a shared contact hole.

2. The method for forming the shared contact hole according to claim 1, further comprising before performing the planarization process, forming a silicide layer located between two adjacent ones of the plurality of gate structures and on the two or more active regions, and forming a second dielectric layer above the silicide layer and between the two adjacent ones of the plurality of gate structures, and wherein the plurality of gate structures each comprises a metal gate.

3. The method for forming the shared contact hole according to claim 2, wherein a material of the metal gates comprises one or more of aluminum, titanium, tantalum, zirconium, cobalt, nickel, and oxides thereof.

4. The method for forming the shared contact hole according to claim 1, wherein a thickness of the first hard mask layer is equal to a thickness of the second hard mask layer.

5. The method for forming the shared contact hole according to claim 4, wherein the first etching process applies an etchant having a high etch selectivity ratio of the first interlayer dielectric layer with respect to the first hard mask layer or the second hard mask layer, and wherein the second etching process applies an etchant having a high etch selectivity ratio of the first hard mask layer or the second hard mask layer with respect to the first interlayer dielectric layer.

6. The method for forming the shared contact hole according to claim 1, wherein a material of the first hard mask layer comprises one or more of silicon oxide, silicon nitride, silicon oxynitride, silicon carbide, silicon carbonitride, boron nitride, tantalum nitride, or titanium nitride, and wherein a material of the second hard mask layer comprises one or more of silicon oxide, silicon nitride, silicon oxynitride, silicon carbide, silicon carbonitride, boron nitride, tantalum nitride, or titanium nitride.

7. The method for forming the shared contact hole according to claim 2, further comprising, after forming the shared contact hole, depositing a metal to form a conductive layer to fill the shared contact hole, wherein the conductive layer is in contact with the silicide layer and the metal gate to form an electrical connection.

8. The method for forming the shared contact hole according to claim 1, wherein the semiconductor substrate comprises an NMOS device region, and the plurality of gate structures are formed on the semiconductor substrate of the NMOS device region.

9. A semiconductor structure, wherein the semiconductor structure is formed by the method for forming the shared contact hole according to claim 8, comprising:
a semiconductor substrate, wherein two or more active regions and shallow trench isolation located between the two or more active regions are formed on the semiconductor substrate, and a plurality of gate structures are formed on the two or more active regions;
a first hard mask layer, wherein the first hard mask layer is located on top of the plurality of gate structures and covers a region where a shared contact hole needs to be formed;
a first interlayer dielectric layer, wherein the first interlayer dielectric layer covers the plurality of gate structures and the first hard mask layer;
a shared contact hole, wherein the shared contact hole is located on the plurality of gate structures and exposes portions of the two or more active regions and the plurality of gate structures; and
a conductive layer, wherein the conductive layer fills the shared contact hole and in contact with the two or more active regions and the plurality of gate structures.

10. The semiconductor structure of claim 9, wherein a material of the metal gate comprises one or more of aluminum, titanium, tantalum, zirconium, cobalt, nickel, and oxides thereof.
